(19) United States
(12) Patent Application Publication
(10) Pub. No.: US 2021/0151354 A1
(43) Pub. Date: May 20, 2021

(54) SEMICONDUCTOR-DEVICE-FORMED SAPPHIRE SUBSTRATE, METHOD OF MANUFACTURING SEMICONDUCTOR-DEVICE-FORMED SAPPHIRE SUBSTRATE, AND METHOD OF TRANSFERRING SEMICONDUCTOR DEVICE

(71) Applicant: V TECHNOLOGY CO., LTD., Yokohama-shi, Kanagawa (JP)

(72) Inventors: Yoshikatsu YANAGAWA, Yokohama-shi, Kanagawa (JP); Takafumi HIRANO, Yokohama-shi, Kanagawa (JP); Koichiro FUKAYA, Yokohama-shi, Kanagawa (JP)

(73) Assignee: V TECHNOLOGY CO., LTD., Yokohama-shi, Kanagawa (JP)

(21) Appl. No.: 17/048,763

(22) PCT Filed: Apr. 16, 2019
(86) PCT No.: PCT/JP2019/016277

§ 371 Date: Oct. 19, 2020

(30) Foreign Application Priority Data
Jun. 19, 2018 (JP) 2018-115723
Aug. 24, 2018 (JP) 2018-157485

(51) Int. Cl. H01L 21/78; H01L 23/00; H01L 33/00; H01L 25/075

(52) U.S. Cl. CPC H01L 21/7806; H01L 24/83; H01L 24/32; H01L 33/0093; H01L 33/007; H01L 21/268; H01L 2224/32225; H01L 2224/83005; H01L 2224/83986; H01L 2924/1033; H01L 25/0753

(57) ABSTRACT

A semiconductor device can be transferred onto a circuit board with high accuracy, and a man-hour and a facility load in a process of peeling off the semiconductor device from a sapphire substrate are reduced. A semiconductor-device-formed sapphire substrate in which gallium-nitride-based semiconductor devices are arrayed and formed on a sapphire substrate includes a nitrogen-gallium re-fusion layer A at an interface between the sapphire substrate and the semiconductor devices. An adhesive strength of the nitrogen-gallium re-fusion layer is smaller than an adhesive strength of an adhesive layer for bonding the semiconductor devices to a circuit board.

### TECHNICAL FIELD

The present invention relates to a semiconductor-device-formed sapphire substrate, a method of manufacturing the semiconductor-device-formed sapphire substrate, and a method of transferring a semiconductor device.

### BACKGROUND ART

Because of the small lattice mismatch between sapphire and gallium nitride, a method of manufacturing a semiconductor device by depositing gallium-nitride-based semiconductor material on a sapphire substrate is widely used.

Meanwhile, since sapphire is inferior in thermal conductivity and electrical conductivity, sapphire may not be suitable for a manufactured semiconductor device. Thus, the semiconductor device is peeled off from the sapphire substrate and, then, is mounted on a predetermined circuit board.

In the related art, laser lift-off (LLO) has been known as a method of peeling off a gallium-nitride-based semiconductor device from the sapphire substrate.

The laser lift-off is a method of peeling off the gallium-nitride-based semiconductor device from the sapphire substrate by applying a laser beam to the vicinity of an interface with the gallium-nitride-based semiconductor device from a back surface of the sapphire substrate (see Patent Literature 1, for example).

Usually, since it is difficult to handle the gallium-nitride-based semiconductor device separated from the sapphire substrate, a method of transferring the semiconductor device to the circuit board after the laser lift-off is performed the semiconductor device on an adhesive film or the like has been adopted.

### CITATION LIST

### Patent Literature

Patent Literature 1: JP 2002-182580 JP

### SUMMARY OF INVENTION

### Technical Problem

However, a method of performing laser lift-off on the semiconductor device once placed on the adhesive film or the like has a problem that since not only the adhesive film is required but also an apparatus for handling the adhesive film is required, the number of manufacturing processes increases.

When the adhesive film is deformed, the semiconductor device transferred onto the adhesive film is misaligned, and thus, there is a problem that the semiconductor device cannot be transferred onto the circuit board with high accuracy.

Generally, the semiconductor device is provided to a user of the semiconductor device while being arranged on the sapphire substrate. Thus, when the user of the semiconductor device performs laser lift-off, an apparatus for handling the adhesive film and an apparatus for performing the laser lift-off are required, and thus, there is a problem of increasing cost.

In order to solve the above problems, an object of the present invention is to provide a semiconductor-device-formed sapphire substrate from which a semiconductor device can be transferred onto a circuit board with high accuracy and with which a man-hour and a facility load in a process of peeling off the semiconductor device from the sapphire substrate can be reduced, a method of manufacturing the semiconductor-device-formed sapphire substrate, and a method of transferring the semiconductor device.

### Solution to Problem

In order to solve the above problems, a semiconductor-device-formed sapphire substrate according to the present invention is a semiconductor-device-formed sapphire substrate on which gallium-nitride-based semiconductor devices are arrayed and formed on a sapphire substrate. The semiconductor-device-formed sapphire substrate includes a nitrogen-gallium re-fusion layer at an interface between the sapphire substrate and the semiconductor devices. An adhesive strength of the nitrogen-gallium re-fusion layer is smaller than an adhesive strength of an adhesive layer that bonds the semiconductor devices to a circuit board.

As described above, the semiconductor-device-formed sapphire substrate according to the present invention includes the nitrogen-gallium re-fusion layer at the interface between the sapphire substrate and the semiconductor device.

This nitrogen-gallium re-fusion layer is formed by applying the laser beam to the semiconductor device with the energy density lower than the energy density of the laser beam with which the semiconductor device peels off from the sapphire substrate. Thus, this nitrogen-gallium re-fusion layer is a fragile layer formed by re-solidified gallium or a part of gallium nitride that is not ablated, and is held by this nitrogen-gallium re-fusion layer in a state in which the semiconductor device does not peel off from the sapphire substrate.

The nitrogen-gallium re-fusion layer has the adhesive strength lower than the adhesive strength of the adhesive layer that bonds the semiconductor device to the circuit board. Thus, the semiconductor device can easily peel off from the sapphire substrate by using the adhesive strength of the adhesive layer used when the semiconductor device is bonded to the circuit board.

As a result, it is not necessary for a user of the semiconductor device to prepare an apparatus for handling the adhesive film or an apparatus for performing the laser lift-off, and it is possible to reduce a man-hour and a facility load in a process of peeling off the semiconductor device from the sapphire substrate. The semiconductor device of the sapphire substrate can be directly transferred onto the circuit board without using the adhesive film or the like, and high-accuracy transfer can be performed.

Here, the adhesive strength of the nitrogen-gallium re-fusion layer at the interface between the sapphire substrate and the semiconductor devices is equal to or less than 230 kg/cm² in shear strength.

An adhesive strength of a typical adhesive layer that is used when the semiconductor device is bonded to the circuit board via the adhesive layer is approximately 100 kg/cm² to 400 kg/cm² although the adhesive strength depends on a type of an adhesive. Thus, the semiconductor device can peel off from the sapphire substrate by using the general adhesive layer.

The shear strength of the nitrogen-gallium re-fusion layer may be preferably smaller than the adhesive strength of the adhesive layer as described above, and may be more preferably less than 100 kg/cm².

In order to solve the above problems, a method of manufacturing a semiconductor-device-formed sapphire substrate according to the present invention is a method of manufacturing a semiconductor-device-formed sapphire substrate including forming gallium-nitride-based semiconductor devices on a sapphire substrate, and performing a peeling pretreatment of peeling the semiconductor devices off from the sapphire substrate. The peeling pretreatment includes a process of forming a nitrogen-gallium re-fusion layer by applying a laser beam to an interface between the semiconductor devices and the sapphire substrate from a back surface side of the sapphire substrate. The laser beam used in the process is applied with an energy density lower than an energy density of a laser beam with which the semiconductor devices peel off from the sapphire substrate. After the laser beam is applied, the sapphire substrate and the semiconductor devices are held by the nitrogen-gallium re-fusion layer with an adhesive strength smaller than an adhesive strength of an adhesive layer that bonds the semiconductor devices to a circuit board.

As described above, in accordance with the method of manufacturing a semiconductor-device-formed sapphire substrate according to the present invention, the laser beam is applied to the interface between the semiconductor device and the sapphire substrate with the energy density lower than the energy density of the laser beam. With this, the semiconductor device peels off from the sapphire substrate, and thus, the nitrogen-gallium re-fusion layer can be easily formed.

Since the adhesive strength of the nitrogen-gallium re-fusion layer is smaller than the adhesive strength of the adhesive layer that bonds the semiconductor device to the circuit board, the semiconductor device can easily peel off from the sapphire substrate by the adhesive strength of the adhesive layer which is used when the semiconductor device is bonded to the circuit board in the subsequent process.

Here, it is desirable that the sapphire substrate and the semiconductor device are held by the nitrogen-gallium re-fusion layer having a shear strength of 230 kg/cm² or less.

It is desirable that the laser beam in the process of forming the nitrogen-gallium re-fusion layer is applied to each of the gallium-nitride-based semiconductor devices multiple times.

As described above, since the energy density of the laser beam varies, when a connection layer is formed by one application, there is a concern that the semiconductor device peels off from the sapphire substrate. Thus, it is desirable that the energy density of the laser beam is reduced and the laser beam is applied multiple times.

In order to solve the above problems, a method of manufacturing a semiconductor-device-formed sapphire substrate according to the present invention is a method of manufacturing a semiconductor-device-formed sapphire substrate on which gallium-nitride-based semiconductor devices are formed on a sapphire substrate. The method includes a peeling preprocessing process of peeling the semiconductor devices off from a sapphire substrate, which is performed after the gallium-nitride-based semiconductor devices are formed. In the peeling pretreatment process, a laser beam having an energy density lower than an energy density of a laser beam with which the gallium-nitride-based semiconductor devices peel off from the sapphire substrate is applied multiple times to an interface between the gallium-nitride-based semiconductor devices and the sapphire substrate from a back surface side of the sapphire substrate.

As described above, by applying the laser beam having the energy density lower than the energy density of the laser beam with which the gallium-nitride-based semiconductor device peels off from the sapphire substrate from the back surface side of the sapphire substrate multiple times, processing can be performed that makes easily peel off the semiconductor device from the sapphire substrate even though the semiconductor device does not peel off from the sapphire substrate.

Here, it is preferable that, in the peeling pretreatment process, the laser beam is applied from the back surface side of the sapphire substrate while applying pressure between the gallium-nitride-based semiconductor devices and the sapphire substrate.

When the laser beam is applied from the back surface side of the sapphire substrate while applying pressure between the semiconductor device and the sapphire substrate, the condition, process margin, under which the nitrogen-gallium re-fusion layer may be formed in the peeling pretreatment is widened.

In the peeling pretreatment process, a region of the interface between the gallium-nitride-based semiconductor devices and the sapphire substrate may be divided into a plurality of regions, and the laser beam may be applied from the back surface side of the sapphire substrate.

The method of dividing the region of the interface between the semiconductor device and the sapphire substrate into the plurality of regions and applying the laser beam has the same effect as the method of applying the laser beam while applying pressure between the semiconductor device and the sapphire substrate.

In order to perform such an application method, it is preferable that in the peeling pretreatment process, the laser beam is applied from the back surface side of the sapphire substrate through a projection mask designed to apply the laser beam to a region smaller than the region of the interface between the gallium-nitride-based semiconductor devices and the sapphire substrate.

In order to solve the above problems, a method of transferring a semiconductor device from a sapphire substrate according to the present invention is a method of transferring a semiconductor device from a sapphire substrate. The method includes a process of preparing the semiconductor-device-formed sapphire substrate or a semiconductor-device-formed sapphire substrate manufactured by the method of manufacturing the semiconductor-device-formed sapphire substrate, a process of forming, on the semiconductor devices on the sapphire substrate or a circuit board, an adhesive layer having an adhesive strength larger than an adhesive strength of a nitrogen-gallium re-fusion layer at an interface between the sapphire substrate and the semiconductor devices, an alignment process of aligning the semiconductor devices arrayed on the sapphire substrate with the circuit board, a bonding process of bonding the semiconductor devices to the circuit board via the adhesive layer while pressurizing the sapphire substrate against the circuit board, and a peeling and arrangement process of peeling the semiconductor devices off from the sapphire substrate by the adhesive strength of the adhesive layer, and arranging the semiconductor devices on the circuit board.

As described above, in accordance with the method of transferring a semiconductor device from a sapphire substrate according to the present invention, the semiconductor device can easily peel off from the sapphire substrate by bonding the semiconductor device to the circuit board via the adhesive layer.

It is not necessary for a purchaser of the semiconductor device to prepare an apparatus for handling the adhesive film or an apparatus for performing the laser lift-off, and it is possible to reduce a man-hour and a facility load in the process of peeling off the semiconductor device from the sapphire substrate. Since the semiconductor device can be directly transferred onto the circuit board without using the adhesive film or the like, high-accuracy transfer can be performed.

### Advantageous Effects of Invention

According to the present invention, it is possible to obtain a semiconductor-device-formed sapphire substrate from which a semiconductor device can be transferred onto a circuit board with high accuracy and with which a man-hour and a facility load in a process of peeling off the semiconductor device from the sapphire substrate can be reduced, a method of manufacturing the semiconductor-device-formed sapphire substrate, and a method of transferring the semiconductor device.

### BRIEF DESCRIPTION OF DRAWINGS

FIG. 1 is a schematic sectional view illustrating a semiconductor-device-formed sapphire substrate according to the present invention;

FIG. 2 is a schematic configuration diagram illustrating an example of an apparatus configuration for implementing a method of manufacturing a semiconductor-device-formed sapphire substrate according to the present invention;

FIG. 3 is a plan view illustrating semiconductor devices formed on a sapphire substrate;

FIG. 4 is a side view of FIG. 3;

FIG. 5 is a flowchart illustrating a procedure of a method of manufacturing a semiconductor-device-formed sapphire substrate and a method of transferring a semiconductor device according to the present invention;

FIG. 6 is a schematic configuration diagram for describing a process of step S2 of FIG. 5;

FIG. 7 is a schematic configuration diagram for describing a process of step S3 of FIG. 5;

FIG. 8 is a schematic configuration diagram for describing a process of step S4 of FIG. 5;

FIG. 9 is a schematic configuration diagram for describing a process of step S5 of FIG. 5;

FIG. 10 is a diagram illustrating a relationship between an energy density of a laser beam, the number of times of application (the number of shots), and a condition under which the semiconductor device peels off from the sapphire substrate;

FIG. 11 is a diagram illustrating a method of using a transparent plate, such as quartz glass, as a method of applying pressure between the semiconductor device and the sapphire substrate;

FIG. 12 is a diagram illustrating a method of using an adhesive film as the method of applying pressure between the semiconductor device and the sapphire substrate;

FIG. 13 is a diagram illustrating a relationship between an energy density of a laser beam and the number of times of application (the number of shots) when the laser beam is applied from a back surface side of the sapphire substrate while applying pressure between the semiconductor device and the sapphire substrate and a condition that the semiconductor device peels off from the sapphire substrate;

FIG. 14 is a diagram illustrating a method of applying the laser beam with dividing a region of an interface between the semiconductor device and the sapphire substrate into a plurality of regions; and

FIG. 15 is a diagram illustrating a method of applying the laser beam with dividing the region of the interface between the semiconductor device and the sapphire substrate into the plurality of regions.

### DESCRIPTION OF EMBODIMENTS

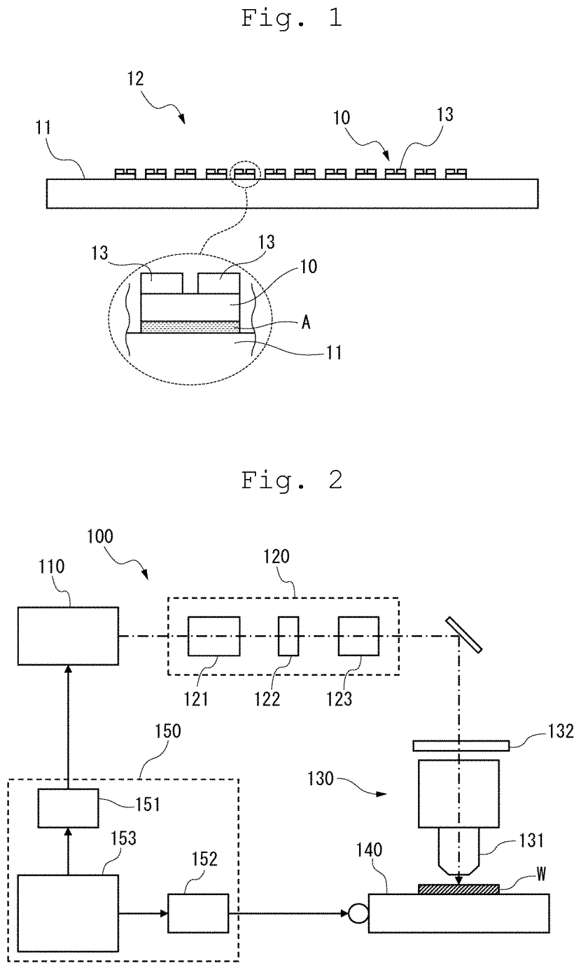

First, an embodiment of a semiconductor-device-formed sapphire substrate according to the present invention will be described with reference to FIG. 1.

As illustrated in FIG. 1, a semiconductor-device-formed sapphire substrate 12 has gallium-nitride-based semiconductor devices 10 arrayed on a sapphire substrate 11. A generally known method can be used as a method of forming the gallium-nitride-based semiconductor devices 10 on the sapphire substrate 11.

Examples of the semiconductor devices include gallium-nitride-based light-emitting diodes (LEDs). For example, in the case of the semiconductor device 10 made of a gallium-nitride-based semiconductor material such as the light-emitting diode (LED), the sapphire substrate 11 having a small lattice mismatch with gallium nitride is suitably used.

The gallium-nitride-based semiconductor material is not limited to pure gallium nitride, but may be a semiconductor material containing a small amount of aluminum or indium which is the same group 3 element as gallium.

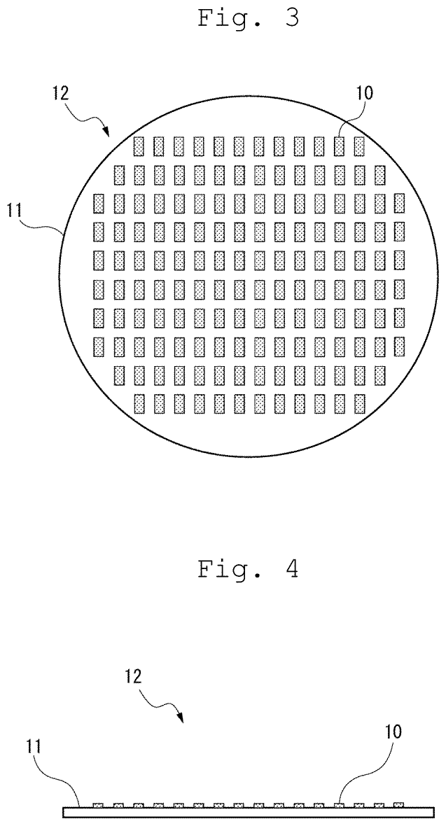

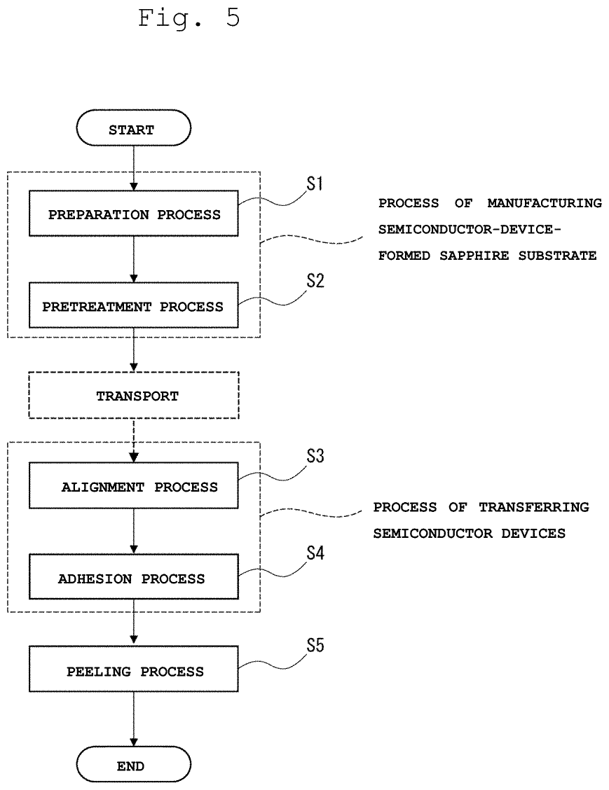

These gallium-nitride-based light-emitting diodes (LEDs) are formed and arranged in a matrix on a main surface of the sapphire substrate 11 as illustrated in FIGS. 3 and 4. A size of one semiconductor device 10 is about 20 to about 80 μm, and a thickness is about several μm to about 10 μm.

As illustrated in FIG. 1, a nitrogen-gallium re-fusion layer A is formed (on an interface) between the sapphire substrate 11 and the semiconductor devices 10.

As will be described in detail later in a method of manufacturing a semiconductor-device-formed sapphire substrate, this nitrogen-gallium re-fusion layer A is formed by applying a laser beam to the interface between the semiconductor devices 10 and the sapphire substrate 11 from a back surface side of the sapphire substrate 11. An energy density of the laser beam in this case is lower than an energy density of the laser beam with which the semiconductor devices 10 peel off from the sapphire substrate 11 by ablation of gallium nitride.

Although the composition of the nitrogen-gallium re-fusion layer A is not clear, when the laser beam having a low energy density is applied, since the gallium nitride decomposes into gallium and nitrogen, the nitrogen-gallium re-fusion layer A is estimated to contain gallium that is subsequently re-solidified or some gallium nitride that is not ablated.

The semiconductor devices 10 of the semiconductor-device-formed sapphire substrate 12 on which the nitrogen-gallium re-fusion layer A is formed are held on the sapphire substrate 11 without peeling off from the sapphire substrate 11.

Specifically, the sapphire substrate 11 and the semiconductor devices 10 are connected by the nitrogen-gallium re-fusion layer having a shear strength of 230 kg/cm² or less.

Meanwhile, although an adhesive strength depends on a type of an adhesive, an adhesive strength (shear strength) of a general adhesive layer used for bonding the semiconductor devices 10 to a circuit board is approximately 100 kg/cm² to 400 kg/cm².

Thus, since the shear strength of the nitrogen-gallium re-fusion layer is 230 kg/cm² or less which is smaller than the adhesive strength of the adhesive layer for bonding the semiconductor devices to the circuit board, the semiconductor devices can easily peel off from the sapphire substrate by the adhesive strength of the adhesive layer used when the semiconductor devices is bonded to the circuit board. The shear strength of the nitrogen-gallium re-fusion layer may be preferably smaller than the adhesive strength of the adhesive layer as described above, and may be more preferably less than 100 kg/cm².

Method of Manufacturing Semiconductor-Device-Formed Sapphire Substrate

An embodiment of the method of manufacturing a semiconductor-device-formed sapphire substrate according to the present invention will be described with reference to FIGS. 2 to 6.

First, an apparatus for implementing the method of manufacturing a semiconductor-device-formed sapphire substrate according to the present invention will be described with reference to FIG. 2. FIG. 2 is a diagram illustrating an example of an apparatus configuration for implementing the method of manufacturing a semiconductor-device-formed sapphire substrate according to the present invention, and the apparatus for implementing the method of manufacturing a semiconductor-device-formed sapphire substrate according to the present invention is not particularly limited to the apparatus illustrated in FIG. 2.

As illustrated in FIG. 2, the apparatus (laser beam machining apparatus) 100 for implementing the method of manufacturing a semiconductor-device-formed sapphire substrate includes a laser head 110, a uniform optical system 120, a microscope unit 130, a machining stage 140, and a control unit 150.

For example, a laser head that outputs a picosecond laser having a wavelength of 263 nm (FHG) with a pulse width of 10 ps can be used as the laser head 110.

The uniform optical system 120 is to make the laser beam that the laser head 110 outputs have a uniform intensity distribution and includes a beam expander lens 121, a homogenizer 122, and a condenser lens 123.

The beam expander lens 121 expands a beam diameter of the laser beam output from the laser head 110, and the homogenizer 122 homogenizes an intensity distribution of a laser beam having an expanded beam diameter.

The condenser lens 123 reduces the beam diameter of the laser beam again, and thus, the laser beam output from the laser head 110 can have a uniform intensity distribution as a whole.

The microscope unit 130 is used for applying the laser beam output from the laser head 110 to a workpiece W with an appropriate energy density.

The microscope unit 130 includes an objective lens 131 and a projection mask 132, and is used for concentrating a laser beam having a desired shape defined by the projection mask 132 on the workpiece W on the machining stage 140 by the objective lens 131.

An XYθ stage that is horizontally movable in up, down, left, and right directions and a rotation direction is preferably used as the machining stage 140.

The control unit 150 links an intensity and a timing of the laser beam output from the laser head 110 with the movement of the workpiece W performed by the machining stage 140.

The control unit 150 includes a laser power supply and control unit 151, a stage control unit 152, and a control computer 153. The laser power supply and control unit 151 controls an output of the laser head 110, the stage control unit 152 controls the movement of the machining stage 140, and the control computer 153 controls the laser power supply and control unit 151 and the stage control unit 152.

Accordingly, the intensity and timing of the laser beam output from the laser head 110 and the movement of the workpiece W performed by the machining stage 140 can be linked.

Next, the method of manufacturing a semiconductor-device-formed sapphire substrate will be described with reference to FIGS. 3 to 6.

FIGS. 3 and 4 are diagrams illustrating an example of the semiconductor devices formed on the sapphire substrate by a general method. FIG. 3 is a plan view, and FIG. 4 is a side view.

The semiconductor devices 10 are formed on the sapphire substrate 11 by crystal growth. A crystal of the gallium-nitride-based semiconductor material grows as a substantial extension of a sapphire crystal lattice on the sapphire substrate 11, and thus, the semiconductor devices are formed.

As described above, the gallium-nitride-based semiconductor material may be not only pure gallium nitride but also a semiconductor material containing a small amount of aluminum or indium that is of the same group 3 element as gallium.

As illustrated in FIGS. 3 and 4, a plurality of semiconductor devices 10 is generally formed on one sapphire substrate 11. Electrodes 13 required for the following description are provided on the semiconductor devices 10 (see FIG. 1).

Other detailed configurations of the semiconductor device 10 do not influence the implementation of the invention, and the description thereof is omitted.

The semiconductor-device-formed sapphire substrate 11 on which the semiconductor devices 10 are arrayed and formed on the sapphire substrate 11 illustrated in FIGS. 3 and 4 formed in this manner is prepared (step S1 of FIG. 5).

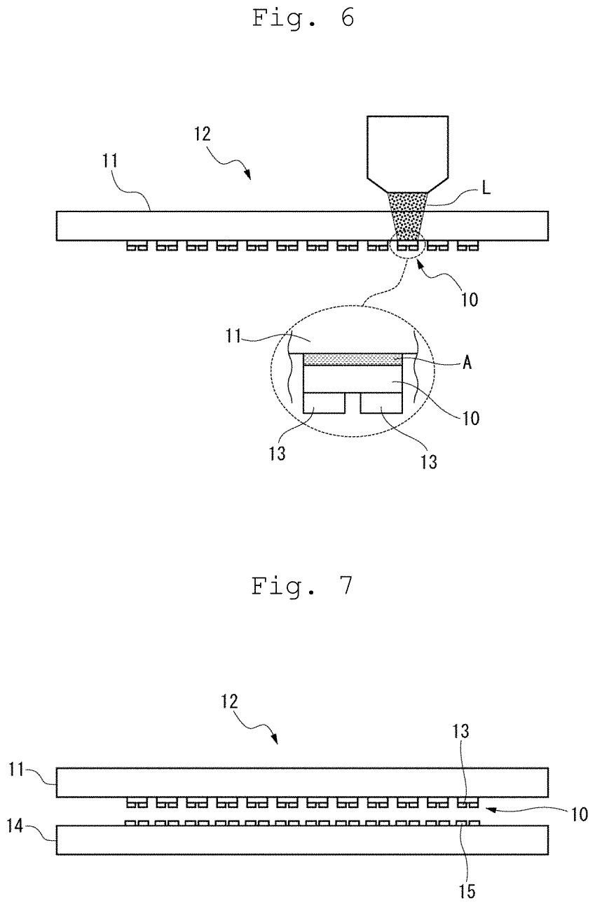

Next, as illustrated in FIG. 6, a nitrogen-gallium re-fusion layer forming process (pretreatment process) for peeling off the substrate 11 from the semiconductor devices 10 is performed (step S2 of FIG. 5).

This pretreatment process (step S2) is performed by using the laser beam machining apparatus 100 (see FIG. 2) described above. FIG. 6 illustrates a state of the semiconductor-device-formed sapphire substrate in step S2.

In this step S2, the nitrogen-gallium re-fusion layer A is formed by applying a laser beam L to the interface between the semiconductor devices 10 and the sapphire substrate 11 from the back surface side of the sapphire substrate 11.

At this time, the laser beam is applied with an energy density lower than an energy density of the laser beam L with which the semiconductor devices peel off from the sapphire substrate.

The energy density lower than the energy density of the laser beam with which the semiconductor devices peel off from the sapphire substrate means an energy density lower than an energy density used in general conventional laser lift-off.

For example, the energy density used in the laser lift-off is typically 150 mJ/cm², whereas the energy density of the laser beam L applied in step S2 is less than 150 mJ/cm².

In the general conventional laser lift-off, the gallium nitride in the vicinity of the interface with the substrate 11 to which a laser beam having a high energy density is applied decomposes into gallium and nitrogen, and the interface with the substrate 11 peels off by dissipating a vaporized nitrogen.

Meanwhile, in the case of the laser beam having the low energy density applied in step S2, the gallium nitride decomposes into gallium and nitrogen. However, the vaporized nitrogen is not dissipated, and the sapphire substrate 11 and the semiconductor devices 10 are presumed to be re-fused (the nitrogen-gallium re-fusion layer A is presumed to be formed at the interface between the sapphire substrate 11 and the semiconductor devices 10). Alternatively, a part of the gallium nitride that is not ablated is presumed to remain at the interface between the sapphire substrate 11 and the semiconductor devices 10 (the nitrogen-gallium re-fusion layer A is presumed to be formed).

As a result, the shear strength adhesive strength at the interface between the substrate 11 and the semiconductor devices 10 (nitrogen-gallium re-fusion layer A) is smaller than the adhesive strength when the semiconductor devices 10 is bonded to the circuit board in the subsequent process. For example, the nitrogen-gallium re-fusion layer A has a shear strength of 230 kg/cm² or less.

The laser beam L applied in step S2 is preferably applied to each of the semiconductor devices 10 multiple times, and the number of times of the application for each of the semiconductor devices 10 is preferably 10 or more. The number of times of application is more preferably 10 to 20.

Since the energy density of the laser beam to be applied is not necessarily constant, the laser beam is applied to each of the semiconductor devices multiple times, and thus, variations are canceled. As a result, the energy density of the laser beam can be set so as not to exceed the energy density with which the semiconductor devices 10 peel off from the substrate 11.

The process in this step S2 corresponds to the method of manufacturing a semiconductor-device-formed sapphire substrate according to the embodiment of the present invention, and the semiconductor-device-formed sapphire substrate according to the embodiment of the present invention is manufactured through this step S2.

Semiconductor Device Transfer Method

An embodiment of a method of transferring a semiconductor device according to the present invention will be described with reference to FIGS. 5, 7, 8, and 9.

First, the semiconductor-device-formed sapphire substrate on which the nitrogen-gallium re-fusion layer A described above is formed is prepared.

Meanwhile, although not illustrated, an adhesive layer having the shear strength (adhesive strength) larger than the shear strength (adhesive strength) of the nitrogen-gallium re-fusion layer A is formed on the semiconductor devices on the sapphire substrate or the circuit board.

The semiconductor-device-formed sapphire substrate 12 on which the nitrogen-gallium re-fusion layer A is formed is transported to a circuit board 14 (see FIG. 5), and the semiconductor devices 10 arrayed on the substrate 11 as illustrated in FIG. 7 are aligned with the circuit board 14 (step S3 of FIG. 5).

As illustrated in FIG. 7, electrodes 15 are provided on the circuit board 14. The electrodes 15 are electrically connected to the electrodes 13 provided on the semiconductor devices 10.

Thus, unless the electrodes 15 of the circuit board 14 and the electrodes 13 of the semiconductor devices 10 are accurately aligned, the semiconductor devices 10 cannot be properly conducted.

The semiconductor-device-formed sapphire substrate 12 illustrated in FIG. 7 is in a state in which the semiconductor devices 10 are held by the sapphire substrate 11 via the nitrogen-gallium re-fusion layer A. Thus, the semiconductor devices 10 can be aligned with the circuit board 14 in a state in which high alignment accuracy is maintained during the manufacturing of the semiconductor devices 10.

The alignment accuracy in step S3 is extremely high as compared with a method of aligning the semiconductor devices 10 of the related art on the circuit board 14 after the semiconductor devices are transferred onto an adhesive film.

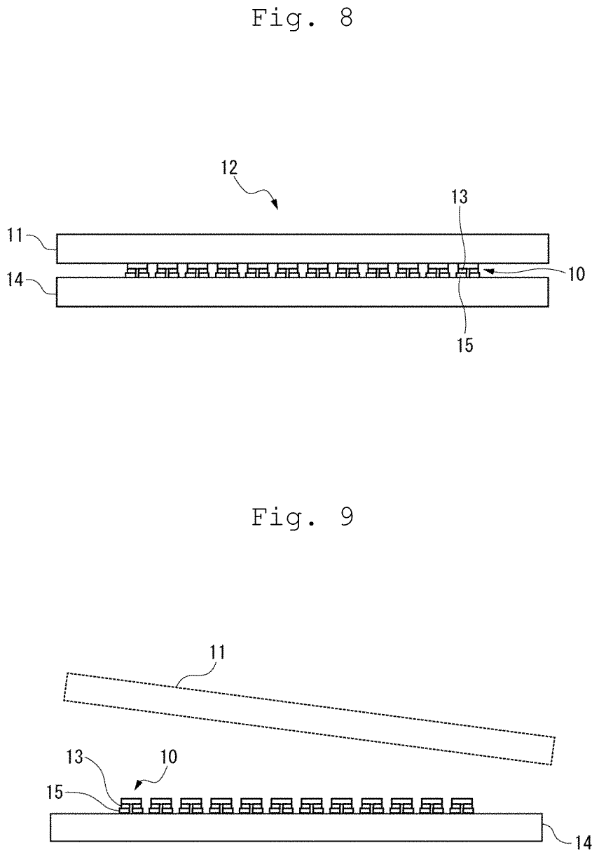

Next, the semiconductor devices 10 is bonded to the circuit board 14 while pressing the semiconductor-device-formed sapphire substrate 12 against the circuit board 14 as illustrated in FIG. 8 (step S4 of FIG. 5).

In the bonding process in step S4, the semiconductor devices 10 is bonded to the circuit board 14 via the adhesive layer by a publicly known method such that the semiconductor devices 10 are fixed to the circuit board 14 while ensuring electrical connection between the electrodes 15 of the circuit board 14 and the electrodes 13 of the semiconductor devices 10.

A typical photosensitive adhesive can be used as the adhesive forming the adhesive layer. As described above, although the adhesive strength depends on the type of the adhesive, the adhesive strength (shear strength) of this adhesive is approximately 100 kg/cm² to 400 kg/cm².

Finally, as illustrated in FIG. 9, a peeling process (step S5 of FIG. 5) of peeling off the sapphire substrate 11 from the semiconductor devices 10 is performed.

In this peeling process, the semiconductor devices 10 peel off from the sapphire substrate 11 by using the adhesive strength of the semiconductor devices 10 to the circuit board 14 (adhesive strength of the adhesive layer). As described above, the adhesive strength (shear strength) of the sapphire substrate 11 to the semiconductor device 10 by the nitrogen-gallium re-fusion layer A is smaller than the adhesive strength (shear strength) of the adhesive layer that bonds the semiconductor devices 10 to the circuit board 14.

Thus, the semiconductor devices 10 peel off from the sapphire substrate 11 by peeling off the sapphire substrate 11 from the circuit board 14. That is, the semiconductor devices 10 are reloaded (transferred) from the sapphire substrate 11 to the circuit board 14.

As described above, the method of transferring a semiconductor device according to the embodiment of the present invention (steps S3 to S5 of FIG. 5) does not include a process of applying a laser beam for peeling off the semiconductor devices in the related art.

Thus, a user of the semiconductor devices can reload (transfer) the semiconductor devices 10 from the sapphire substrate 11 to the circuit board 14 with high accuracy without using a laser beam application apparatus.

Pretreatment Process

Here, details and modifications of the pretreatment process (step S2) described above will be described.

As described above, the pretreatment process (step S2) is performed for easily peeling the semiconductor devices 10 off from the sapphire substrate 11 after the semiconductor devices 10 are formed. The laser beam having an energy density lower than the energy density of the laser beam, with which the semiconductor device 10 peels off from the sapphire substrate 11, from the back surface side of the sapphire substrate 11 is applied to the interface between the semiconductor device 10 and the sapphire substrate 11 multiple times.

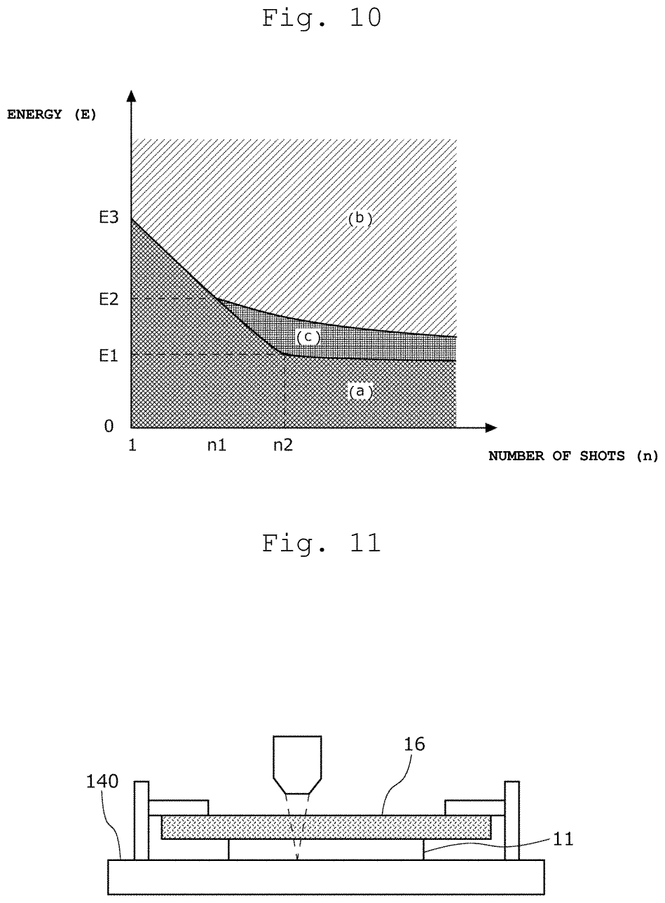

Here, the energy density lower than the energy density of the laser beam with which the semiconductor devices peel off from the sapphire substrate means the energy density lower than the energy density used in the general conventional laser lift-off. FIG. 10 is a diagram illustrating a relationship between the energy density of the laser beam, the number of times of the application (the number of shots), and a condition under which the semiconductor devices peel off from the sapphire substrate.

As illustrated in FIG. 10, a state of the interface between the semiconductor devices 10 and the sapphire substrate 11 after the laser beam is applied to the interface between the semiconductor device 10 and the sapphire substrate 11 from the back surface side of the sapphire substrate 11 is roughly classified into three states. That is, the three states are a state in which an adhesion state between the semiconductor device 10 and the sapphire substrate 11 does not change even after the laser beam is applied (region (a)), a state in which the semiconductor device 10 peels off from the sapphire substrate 11 after the laser beam is applied (region (b)), and a state in which the nitrogen-gallium re-fusion layer is formed between the semiconductor device 10 and the sapphire substrate 11 after the laser beam is applied (region (c)).

A specific composition of the nitrogen-gallium re-fusion layer is not clear, but even in the case of the laser beam having the low energy density, some gallium nitride decomposes into gallium and nitrogen, and thus, a part of the vaporized nitrogen is presumed to be dissipated. Thus, gallium solidified as a simple substance or a part of the gallium nitride that is not ablated is presumed to remain in the nitrogen-gallium re-fusion layer.

As can be seen from a graph represented in FIG. 10, a condition (process margin) under which the nitrogen-gallium re-fusion layer can be formed in the pretreatment process (step S2) is narrow. When the energy density of the laser beam to be applied is lower than E1, the adhesion state between the semiconductor device 10 and the sapphire substrate 11 does not change, and thus, a desired nitrogen-gallium re-fusion layer cannot be formed. Meanwhile, when the energy density of the laser beam to be applied is higher than E3, the semiconductor device 10 peels off from the sapphire substrate 11.

Even though the energy density of the laser beam to be applied is lower than E3, the nitrogen-gallium re-fusion layer cannot be formed unless the number of times of the application using the laser beam (the number of shots) is n1 or more.

Thus, in order to widen the process margin in the pretreatment process (step S2), the following measures may be considered. One is a method of applying the laser beam from the back surface side of the sapphire substrate 11 while applying pressure between the semiconductor device 10 and the sapphire substrate 11, and the other is a method of dividing a region of the interface between the semiconductor device 10 and the sapphire substrate 11 into a plurality of regions and applying the laser beam from the back surface side of the sapphire substrate 11.

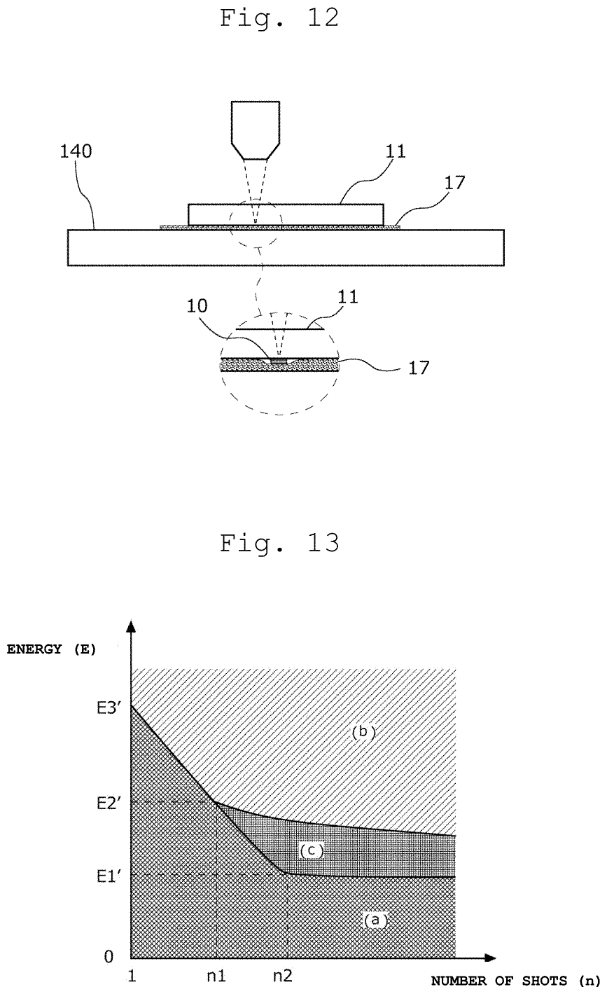

For example, a method using a transparent plate such as quartz glass as illustrated in FIG. 11 or a method using an adhesive film as illustrated in FIG. 12 can be adopted as the method of applying the laser beam from the back surface side of the sapphire substrate 11 while applying pressure between the semiconductor device 10 and the sapphire substrate 11.

As illustrated in FIG. 11, in the method using the transparent plate such as quartz glass, the sapphire substrate 11 is mounted on the machining stage 140 while the semiconductor devices 10 is facing the machining stage 140 side, and the laser beam is applied while pressing the sapphire substrate 11 against the processing stage 140 by using the quartz glass 16.

As illustrated in FIG. 12, in the method using the adhesive film, the laser beam is applied from the back surface side of the sapphire substrate 11 in a state in which an elastic adhesive film 17 is attached to the surface of the sapphire substrate 11 on which the semiconductor devices 10 are formed. As illustrated in a partially enlarged view in FIG. 12, the laser beam is applied from the back surface side of the sapphire substrate 11 in a state in which the semiconductor device 10 is pressurized against the sapphire substrate 11 by the elasticity of the adhesive film 17.

FIG. 13 is a diagram illustrating a relationship between the energy density of the laser beam and the number of times of the application (the number of shots) when the laser beam is applied from the back surface side of the sapphire substrate 11 while applying pressure between the semiconductor device 10 and the sapphire substrate 11 according to the method described above, and the condition under which the semiconductor device peels off from the sapphire substrate.

As can be seen from the comparison of FIG. 13 with FIG. 10, when the laser beam is applied from the back surface side of the sapphire substrate 11 while applying pressure between the semiconductor device 10 and the sapphire substrate 11, the entire graph extends in a vertical direction. This means that the energy density of the laser beam to be applied is higher when the pressurizing is performed than that without pressurizing. Specifically, the energy density of E1 increases to E1′, the energy density of E2 increases to E2′, and the energy density of E3 increases to E3′.

Meanwhile, this means that the condition (process margin) under which the nitrogen-gallium re-fusion layer can be formed in the pretreatment step (step S2) is relaxed. For example, the process margin is an energy density of 50 to 60 mJ/cm² and the number of shots is 20 or more when the pretreatment process (step S2) is performed without pressurizing. In contrast application of the laser beam from the back surface side of the sapphire substrate 11 while applying pressure between the semiconductor device 10 and the sapphire substrate 11 increases the process margin to an energy density of 60 to 100 mJ/cm² and the number of shots to 20 or more. When only the energy density is considered, since the process margin of 10 mJ/cm² increases to 40 mJ/cm², the difference is remarkable.

When the process margin increases, it is easy to form the nitrogen-gallium re-fusion layer in the pretreatment process (step S2), and the incidence of defective products is reduced.

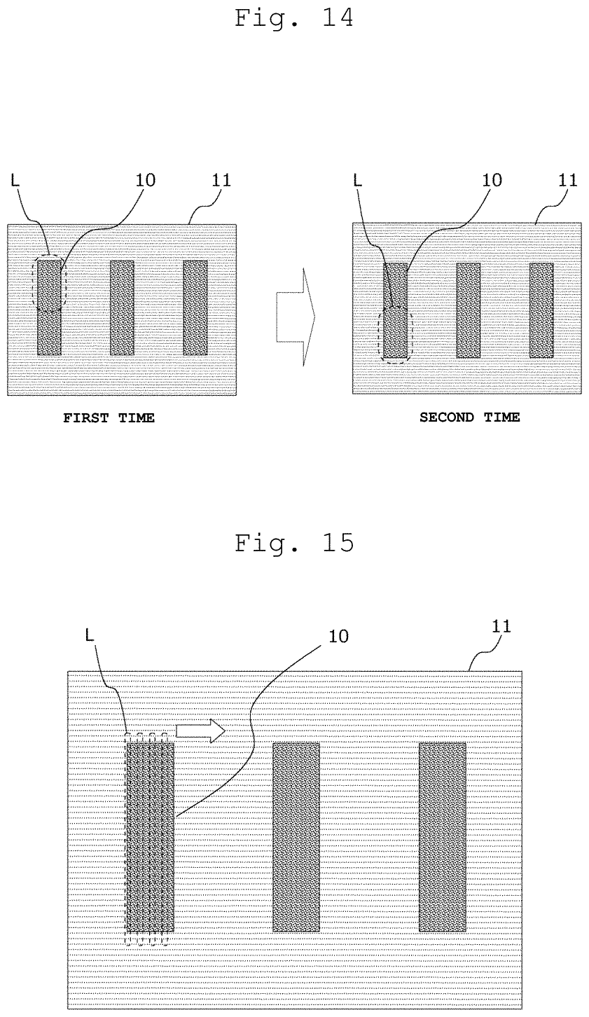

Although the method described above is to add pressure between the semiconductor device 10 and the sapphire substrate 11 by using a separate jig or component. The substantially same effect as the method of applying pressure between the semiconductor device and the sapphire substrate can also be obtained in the method of dividing the region of the interface between the semiconductor device and the sapphire substrate into the plurality of regions and applying the laser beam as illustrated in FIGS. 14 and 15.

Thus, the method of dividing the region of the interface between the semiconductor device and the sapphire substrate into a plurality of regions and applying the laser beam will also be described with reference to FIGS. 14 and 15.

FIG. 14 is a schematic diagram illustrating a state in which the interface between the semiconductor device 10 and the sapphire substrate 11 is observed through the sapphire substrate 11. As illustrated in FIG. 14, in this application method, the region of the interface between the semiconductor device 10 and the sapphire substrate 11 is divided into the plurality of regions, and the laser beam is applied from the back surface side of the sapphire substrate 11.

In the example illustrated in FIG. 14, a laser beam application region L is set to be narrower than the region of the interface between the semiconductor device 10 and the sapphire substrate 11, and laser beam is applied two times to cover the entire region of the interface between the semiconductor device 10 and the sapphire substrate 11.

Although it is assumed that the laser beam is applied multiple times in this pretreatment process (step S2), when the region is divided into the plurality of regions, the laser beam is applied to each region multiple times.

FIG. 15 is a schematic diagram illustrating a state in which the interface between the semiconductor device 10 and the sapphire substrate 11 is observed through the sapphire substrate 11. As illustrated in FIG. 15, in this application method, the region of the interface between the semiconductor device 10 and the sapphire substrate 11 is divided into the plurality of stripes, and the laser beam is moved in an arrow direction in FIG. 15 while applying to a stripe-shaped application region L from the back surface side of the sapphire substrate 11. Even with such an application method, the region of the interface between the semiconductor device 10 and the sapphire substrate 11 is divided into the plurality of regions, and the laser beam is applied to each region multiple times.

In order to form the laser beam application region L as illustrated in FIGS. 14 and 15, the laser beam is preferably applied through a projection mask designed to apply the laser beam to a region smaller than the region of the interface between the semiconductor device 10 and the sapphire substrate 11.

When the laser beam is applied to the application region L smaller than the region of the interface between the semiconductor device 10 and the sapphire substrate 11, the region to which the laser beam is not applied constantly remains. The adhesion state between the semiconductor device 10 and the sapphire substrate 11 is maintained with no change in this region.

Thus, the adhesion strength in the region in which the adhesion state is maintained pressurizes the region to which the laser beam is applied and in which the machining is in progress.

That is, the method of dividing the region of the interface between the semiconductor device 10 and the sapphire substrate 11 into the plurality of regions and applying the laser beam provides the same effect as the method of applying the laser beam while pressurizing the semiconductor device 10 and the sapphire substrate 11.

Although it has been described in the embodiment that the gallium-nitride-based light-emitting diode is used as the gallium-nitride-based semiconductor device, the present invention is not limited thereto.

### REFERENCE SIGNS LIST

10 gallium-nitride-based semiconductor device
11 (sapphire) substrate
12 semiconductor-device-formed sapphire substrate
13 electrode
14 circuit board
15 electrode
100 laser beam machining apparatus

1. A semiconductor-device-formed sapphire substrate on which gallium-nitride-based semiconductor devices are arrayed and formed on a sapphire substrate,
a nitrogen-gallium re-fusion layer at an interface between the sapphire substrate and the semiconductor devices,
wherein an adhesive strength of the nitrogen-gallium re-fusion layer is smaller than an adhesive strength of an adhesive layer that bonds the semiconductor devices to a circuit board.

2. The semiconductor-device-formed sapphire substrate according to claim 1, wherein
the adhesive strength of the nitrogen-gallium re-fusion layer at the interface between the sapphire substrate and the semiconductor devices is equal to or less than 230 kg/cm² in shear strength.

3. A method of manufacturing a semiconductor-device-formed sapphire substrate, comprising:
forming gallium-nitride-based semiconductor devices on a sapphire substrate; and then
performing a peeling pretreatment for peeling the semiconductor devices off from the sapphire substrate,
wherein the peeling pretreatment includes a process of forming a nitrogen-gallium re-fusion layer by applying a laser beam to an interface between the semiconductor devices and the sapphire substrate from a back surface side of the sapphire substrate,
the laser beam used in the process is applied with an energy density lower than an energy density of a laser beam with which the semiconductor devices peel off from the sapphire substrate, and
after the laser beam is applied, the sapphire substrate and the semiconductor devices are held by the nitrogen-gallium re-fusion layer with an adhesive strength smaller than an adhesive strength of an adhesive layer that bonds the semiconductor devices to a circuit board.

4. The method of manufacturing a semiconductor-device-formed sapphire substrate according to claim 3, wherein
the sapphire substrate and the semiconductor devices are held by the nitrogen-gallium re-fusion layer having a shear strength of 230 kg/cm² or less.

5. The method of manufacturing a semiconductor-device-formed sapphire substrate according to claim 3, wherein
the laser beam in the process is applied to each of the gallium-nitride-based semiconductor devices multiple times.

6. The method of manufacturing a semiconductor-device-formed sapphire substrate according to claim 4, wherein
the laser beam in the process is applied to each of the gallium-nitride-based semiconductor devices multiple times.

7. A method of manufacturing a semiconductor-device-formed sapphire substrate on which gallium-nitride-based semiconductor devices are arrayed and formed on a sapphire substrate, the method comprising:
a peeling preprocessing process of peeling the semiconductor devices off from a sapphire substrate, which is performed after the gallium-nitride-based semiconductor, devices are formed,
wherein, in the peeling pretreatment process, a laser beam having an energy density lower than an energy density of a laser beam with which the gallium-nitride-based semiconductor devices to be peeled off from the sapphire substrate is applied to an interface between the gallium-nitride-based semiconductor devices and the sapphire substrate from a back surface side of the sapphire substrate.

8. The method of manufacturing a semiconductor-device-formed sapphire substrate according to claim 7, wherein
in the peeling pretreatment process, the laser beam is applied from the back surface side of the sapphire substrate while applying pressure between the gallium-nitride-based semiconductor devices and the sapphire substrate.

9. The method of manufacturing a semiconductor-device-formed sapphire substrate according to claim 7, wherein
in the peeling pretreatment process, a region of the interface between the gallium-nitride-based semiconductor devices and the sapphire substrate is divided into a plurality of regions, and the laser beam is applied from the back surface side of the sapphire substrate.

10. The method of manufacturing a semiconductor-device-formed sapphire substrate according to claim 9, wherein
in the peeling pretreatment process, the laser beam is applied from the back surface side of the sapphire substrate through a projection mask designed to apply the laser beam to a region smaller than the region of the interface between the gallium-nitride-based semiconductor devices and the sapphire substrate.

11. A method of transferring a semiconductor device from a sapphire substrate, comprising:
a process of preparing the semiconductor-device-formed sapphire substrate according to claim 1;
a process of forming, on the semiconductor devices on the sapphire substrate or a circuit board, an adhesive layer having an adhesive strength larger than an adhesive strength of a nitrogen-gallium re-fusion layer at an interface between the sapphire substrate and the semiconductor devices;
an alignment process of aligning the semiconductor devices arrayed on the sapphire substrate with the circuit board;
a bonding process of bonding the semiconductor devices to the circuit board via the adhesive layer while pressurizing the sapphire substrate against the circuit board; and
a peeling and arrangement process of peeling the semiconductor devices off from the sapphire substrate by the adhesive strength of the adhesive layer and arranging the semiconductor devices on the circuit board.

12. A method of transferring a semiconductor device from a sapphire substrate, comprising:
a process of preparing the semiconductor-device-formed sapphire substrate according to claim 3;
a process of forming, on the semiconductor devices on the sapphire substrate or a circuit board, an adhesive layer having an adhesive strength larger than an adhesive strength of a nitrogen-gallium re-fusion layer at an interface between the sapphire substrate and the semiconductor devices;
an alignment process of aligning the semiconductor devices arrayed on the sapphire substrate with the circuit board;
a bonding process of bonding the semiconductor devices to the circuit board via the adhesive layer while pressurizing the sapphire substrate against the circuit board; and
a peeling and arrangement process of peeling the semiconductor devices off from the sapphire substrate by the adhesive strength of the adhesive layer and arranging the semiconductor devices on the circuit board.

13. A method of transferring a semiconductor device from a sapphire substrate, comprising:
a process of preparing the semiconductor-device-formed sapphire substrate according to claim 7;
a process of forming, on the semiconductor devices on the sapphire substrate or a circuit board, an adhesive layer having an adhesive strength larger than an adhesive strength of a nitrogen-gallium re-fusion layer at an interface between the sapphire substrate and the semiconductor devices;
an alignment process of aligning the semiconductor devices arrayed on the sapphire substrate with the circuit board;
a bonding process of bonding the semiconductor devices to the circuit board via the adhesive layer while pressurizing the sapphire substrate against the circuit board; and
a peeling and arrangement process of peeling the semiconductor devices off from the sapphire substrate by the adhesive strength of the adhesive layer and arranging the semiconductor devices on the circuit board.
